(19) United States
(12) Patent Application Publication
(10) Pub. No.: US 2026/0318673 A1
(43) Pub. Date: Oct. 15, 2026

(54) INTEGRATED METROLOGY

(71) Applicant: NOVA LTD., Rehovot (IL)

(72) Inventors: Alex Shichtman, Rehovot (IL); Gilad Barak, Rehovot (IL); Doron Avraham, Rehovot (IL); Shmuel Feldman, Rehovot (IL); Michael Panich, Rehovot (IL); Shimon YALOV, Rehovot (IL)

(73) Assignee: NOVA LTD., Rehovot (IL)

(21) Appl. No.: 19/486,940

(22) PCT Filed: May 22, 2024
(86) PCT No.: PCT/IB2024/054996

§ 371 Date: Nov. 23, 2025

Related U.S. Application Data
(60) Provisional application No. 63/503,710, filed on May 22, 2023.

(51) Int. Cl. G01B 11/02; H10P 74/20

(52) U.S. Cl. CPC G01B 11/022; G01B 2210/56; H10P 74/203

(57) ABSTRACT

There is provided an integrated system that includes (i) an integrated imaging unit (IIU) configured to scan a sample while the sample is located at a first plane of a first height; (ii) an integrated metrology unit (IMU) configured to measure metrology sites of the sample while the sample is located at a second plane of a second height that differs from the first height; and (iii) a sample movement unit configured to move a sample, by following a path, between the first plane to the second plane; wherein the IIU is located between the first plane and the second plane.

### CROSS REFERENCE

This application claims priority from U.S. provisional patent Ser. No. 63/503,710 filing date May 22 2023 which is incorporated herein in its entirety.

### BACKGROUND

Integrated metrology (IM) plays a central role in semiconductor process control. IM tools are small-footprint modules attached to a fabrication process tool, offering expedient feedback on the processed sample s. Immediately before and\or after the sample goes through processing, characterization is offered by the IM, allowing accurate processing, corrective actions and refinement of the processing parameters for future sample s. IM metrology is based on optical scatterometry, using broadband spectral reflection from the dedicated test sites on the sample, together with advanced interpretation algorithms, to deduce dimensional (and sometimes material) characteristics of the measured structure.

With the increasing complexity and tightening process windows typical of modern semiconductor fabrication, the need for diversified and comprehensive metrology is continuously increasing. The potential of augmenting IM metrology—with its uniquely fast feedback—is of high potential benefit

Unfortunately, IM tools are strictly limited in footprint: an IM tool is placed in a standard-size opening of the processing tool, attached to one of few ports where sample s can be introduced extracted. The allowed dimensions are determined by the size of a standard Front-Opening Universal Pod (FOUP)—the container in which sample s are carried between tools in the semiconductor manufacturing factory (‘Fab’). Such dimensions allow standard integration alongside other FOUPs connected to the tool with no special adaptations. These dimensional restrictions significantly limit the ability of adding more metrology modules and capabilities to IM.

There is a growing need to provide method and systems that provide information about samples that are later inspected or processed by other devices.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates an example of a sample, an integrated system and a sample related system;

FIGS. 2-4 illustrates examples of integrated systems and a sample;

FIGS. 5-15 illustrates examples of parts of integrated systems; and

FIG. 16 illustrates an example of a method; and

FIGS. 17-21 illustrates examples of parts of integrated systems.

### DETAILED DESCRIPTION OF THE DRAWINGS

According to an embodiment, there is provided a compact integrated system that has inspection and metrology capabilities and is compact.

According to an embodiment there is provided an integrated system that includes (i) an integrated imaging unit (IIU) configured to scan a sample while the sample is located at a first plane of a first height; (ii) an integrated metrology unit (IMU) configured to measure metrology sites of the sample while the sample is located at a second plane of a second height that differs from the first height; and (iii) a sample movement unit configured to move a sample, by following a path, between the first plane to the second plane; wherein the IIU is located between the first plane and the second plane.

There are provided several ways for integrating additional measurement modules onto an IM platform, while preserving the core metrology capabilities. With such integrations additional measurement heads can be added, such as bright-field (BF) imaging, dark-field (DF) imaging, sample edge characterization, eddy-current measurement head for metal layer thickness, photoluminescence probe for organics residue detection etc.

There are provided various integration schemes, allowing the combining of additional measurement/inspection modules onto an IM platform. Specifically, the addition of an IIU allowing full-sample imaging, although other possibilities exist for such added measurement heads (as described above).

These solutions comply with the following constraints:
a. Extremely tight space limitations: as described, an integrated system has a limited footprint which cannot be breached. Even the integration of the standard optical head of the IMU poses a significant challenge, and any addition of hardware contents requires innovative solutions.
b. Low cost: integrated system solutions are highly cost-sensitive and cannot be based on expensive hardware.
c. Thermal and environmental considerations: the standard optical metrology offered by the IMU is sensitive to environmental changes, such as temperature drifts and air motion. The addition of the imaging module must not degrade the basic performance of the IMU.
d. Throughput: an integrated system throughput (i.e. number of samples evaluated per hour) is required to be at least as fast as that of the process tool to which it is attached. In no way can the metrology delay the overall operation of the fabrication process. The added imaging metrology must be extremely fast, so that the overall throughput is not affected significantly.

In order to satisfy these requirements several integration schemes are proposed, along with the associated measurement sequences combining an IMU and IIU.

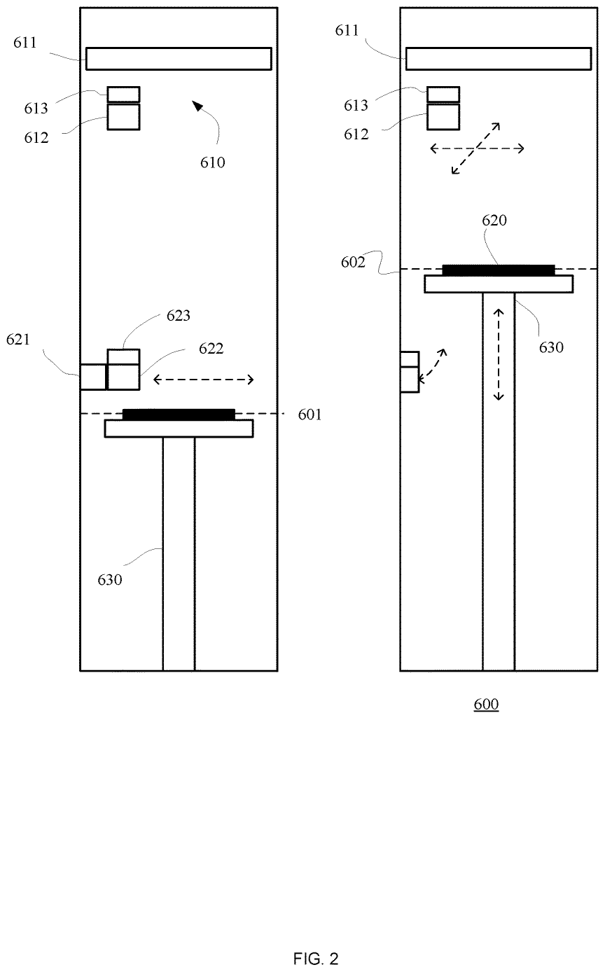

According to an embodiment, the IMU includes an Optical Head (OH) (denoted 612 in FIG. 2) that is movable along one or more exes, and another portion 611 that may be static and is also referred to as an optical layer. The OH is moved by OH movement unit (denoted 613 in FIG. 2).

The OH is placed above the sample, implementing one or more optical measurement such as scatterometry (using spectral reflectometry (SR), polarized SR, spectral ellipsometry, etc. In most implementations, the OH is moved above the sample using a dedicated motion stage (OH movement unit). Alternatives to this approach exist in which the optical head is static, and the sample is moved and rotated, or where both the optical head and sample are moved along different axes (x\y or r\θ). For simplicity, below we commonly assume the sample is static and the OH is moved unless specified otherwise.

An optical layer holds the illumination, optics, beam shaping, focus, collection path and detected components.

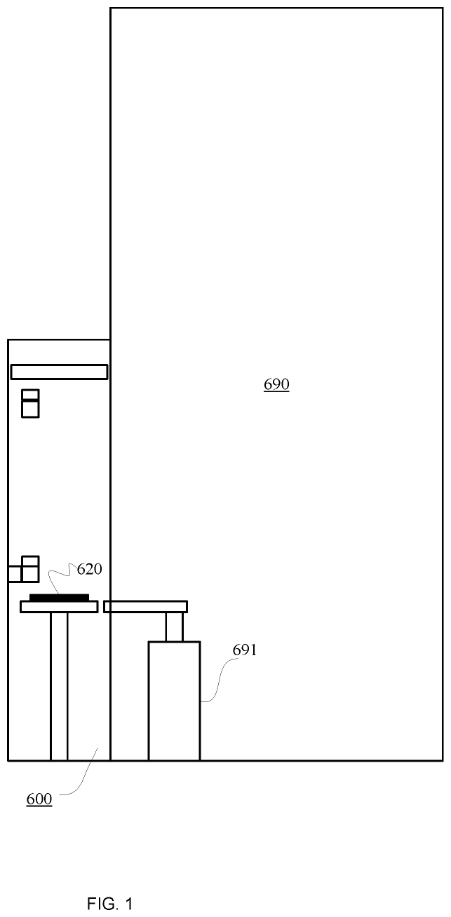

FIG. 1 illustrates an example of the integrated system 600 that is attached to a sample related system 690 such as a sample processing system (for example a manufacturing system) or yet another sample evaluation system. System 690 includes a robot 691 configured to convey the sample 620 from the integrated system to thew sample related system and to the integrated system, FIG. 2 illustrates an example of an integrated system 600 that includes (i) an integrated imaging unit (IIU) 622 configured to scan a sample 620 while the sample is located at a first plane 601 of a first height; (ii) an integrated metrology unit (IMU) 610 configured to measure metrology sites of the sample while the sample is located at a second plane 602 of a second height that differs from the first height; and (iii) a sample movement unit such as stage 630 configured to move a sample, by following a path, between the first plane to the second plane. The IIU is located between the first plane and the second plane. FIG. 2 also illustrates (a) first IIU movement unit 621 that is configured to position the IIU 622 away from the path, during a movement of the sample along the path, and (b) second IIU movement unit 623 that is configured to move the IIU during the scan of the sample.

The positioning of the IIU and the IMU at different heights and the mostly vertical movement of the sample between the IIU and the IMU saves a lot of space and assists in reducing the footprint of the integrated system.

According to an embodiment, the integrated system includes an interface for mechanically coupling the integrated system to the sample related system. The interface may include screws, fastening elements, bolts, threaded elements, magnetic elements, and the like.

The integrated system includes a first IIU movement unit 260-1 that is configured to position the integrated imaging unit away from the path, during a movement of the sample along the path.

According to an embodiment, the integrated system includes a second IIU movement unit 620-2 that is configured to move the IIU during the scan of the sample.

According to an embodiment, the second IIU movement unit includes one or more rails and one or bearings for interfacing with the one or more rails during the movement of the IIU during the scan of the sample. The IIU moves from one side to another; the rails correspond to the movement.

According to an embodiment, the one or more rails are located outside the path of the sample—so that the sample, when moved along the path, does not contact the rails.

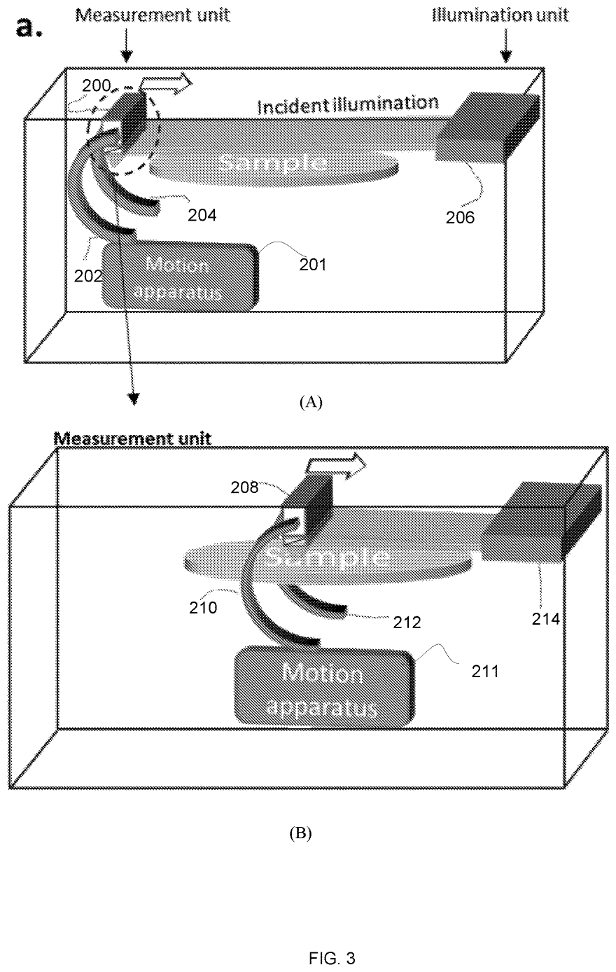

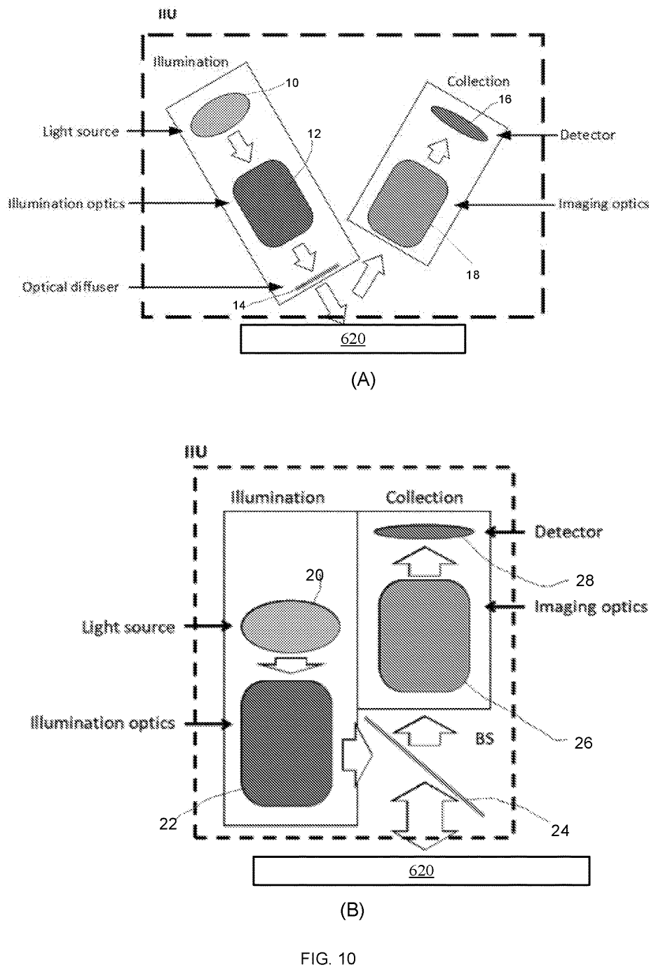

According to an embodiment, the IIU includes a beam splitter (see for example FIG. 3 beam splitter 24), that is shared between an illumination sub-unit (see for example, FIG. 10—illumination sub-unit that includes light source 20 and illumination optics 22) and a collection sub-unit of the IIU (see for example, FIG. 10—collection sub-unit that includes imaging optics 26 and detector 28).

According to an embodiment, the integrated imaging unit is configured to illuminate the sample, during the scan of the sample, by oblique illumination-see for example the top part of FIG. 10 that illustrates oblique illumination and oblique collection—which makes the beam splitter obsolete. The oblique angle may be close to ninety degrees—for example may range between 80 and 89.5 degrees.

According to an embodiment, a dimension (for example width and depth) of the integrated system ranged between one to one and a half times a corresponding dimension of the sample.

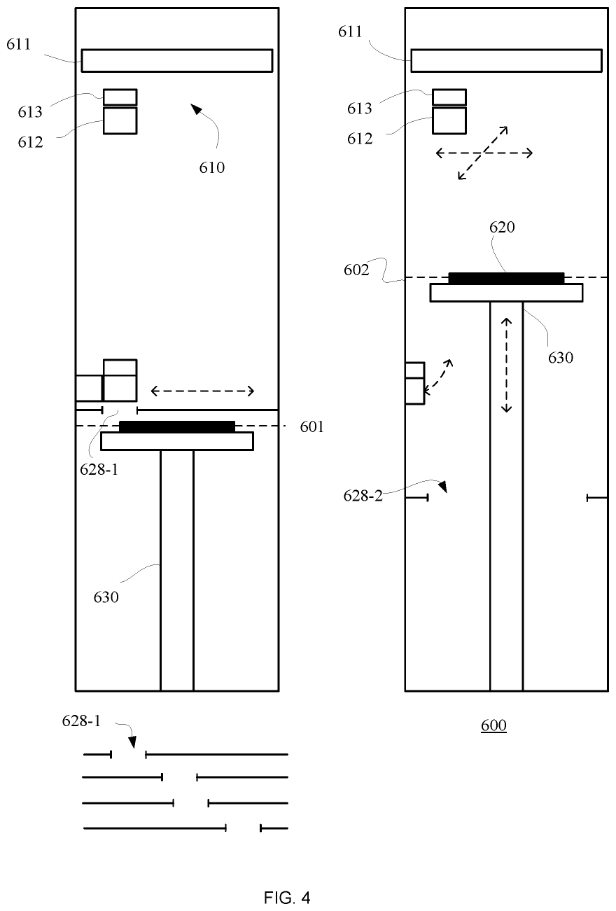

According to an embodiment, the integrated system includes a contamination reduction window configured to reduce contamination within a portion of the integrated system. The contamination reduction window is either static (see FIG. 4, window 628-2) or movable (see FIG. 4, window 628-1)—and follows the movement of the IIU—and is configured to block contaminating particles from propagating towards the IIU and the IMU while allowing the IIU and the IMU to evaluate the sample.

A window can be placed below the IIU and travel with it as it scans across the sample, Alternatively, the window can be connected to the IIU module or moved separately.

According to an embodiment, a window may cover the entire sample and can be placed below the IIU. According to an example, the sample cannot be offset vertically to be placed closer to the OH for IM measurement. Instead, a large working-distance solution is to be used for the OH, allowing it to measure the sample at the required offset to allow the IIU travel. Alternatively—the window is large enough to allow the stage pass through.

This approach offers uniquely spacious available volume for the added metrology. It is thus relatively straightforward to introduce other additional measurement heads to the enclosure.

Folding-module integration: As discussed, available volume inside the IM enclosure is extremely limited. With dedicated design, it could be possible to allocate a several centimeters-wide region at one edge of the enclosure for additional hardware. The availability of such volume is used in the current proposed approach, as well as in some methods described below.

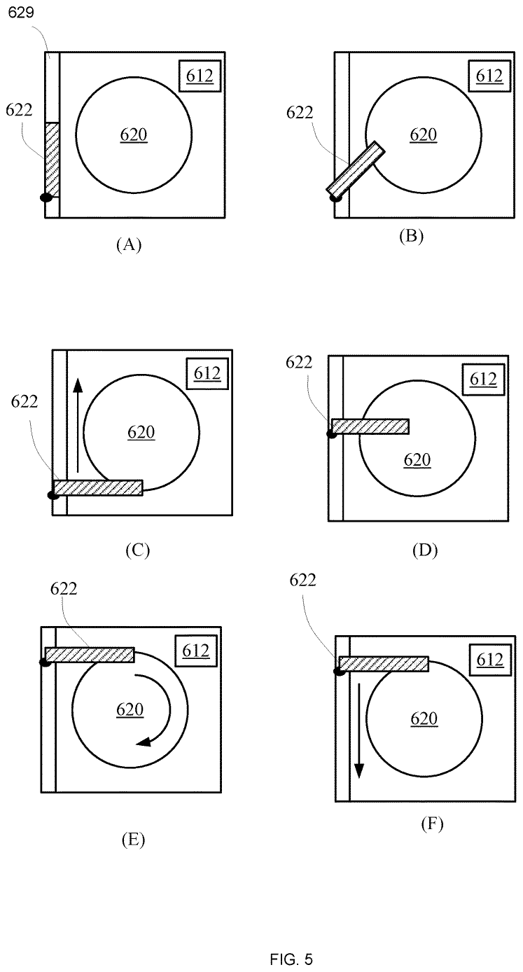

FIG. 5 presents one implementation by which the IIU 625 is stored at a narrow volume (629) near the enclosure edge (FIG. 5 part (A)). The IIU is then rotated into place (FIG. 5 parts (A) and (C)) and scanned across the sample 620 (FIG. 5 part (D)). In this proposed implementation, the IIU is shorter than 300 mm but longer than 150 mm. Under such conditions, a single scan covers (at least) half of the sample area. To cover the second sample half, the sample is rotated by the stage in 180° (FIG. 5 part (E)) and another IIU scan takes place (FIG. 5 part (F)). FIG. 5 also illustrates OH 612 of the IMU.

According to an embodiment-several variations are possible for this approach.

Single-sweep sample coverage. Using an IIU that is longer than the sample (for example is longer than 300 mm), it is possible to cover the full sample extent in a single sweep. Such implementation has several deficiencies compared to the proposed approach, mainly in required volume and cost. Furthermore, it only provides a minor throughput advantage, as the IIU module anyhow has to travel back to its origin location after measurement to clear the volume above the sample for OH motion during IM run.

One possible advantage of such implementation is obtained when the IIU offers multiple different measurement capabilities. Most notably, the ability to collect additional wavelengths for imaging, or measuring both bright field (BF) and dark field (DF) images, which (when using 300 mm-coverage) can be collected at sequentially at both scans across the sample. In such cases, a full-length 300 mm coverage could drastically improve throughput as it reduces the number of sweeps required.

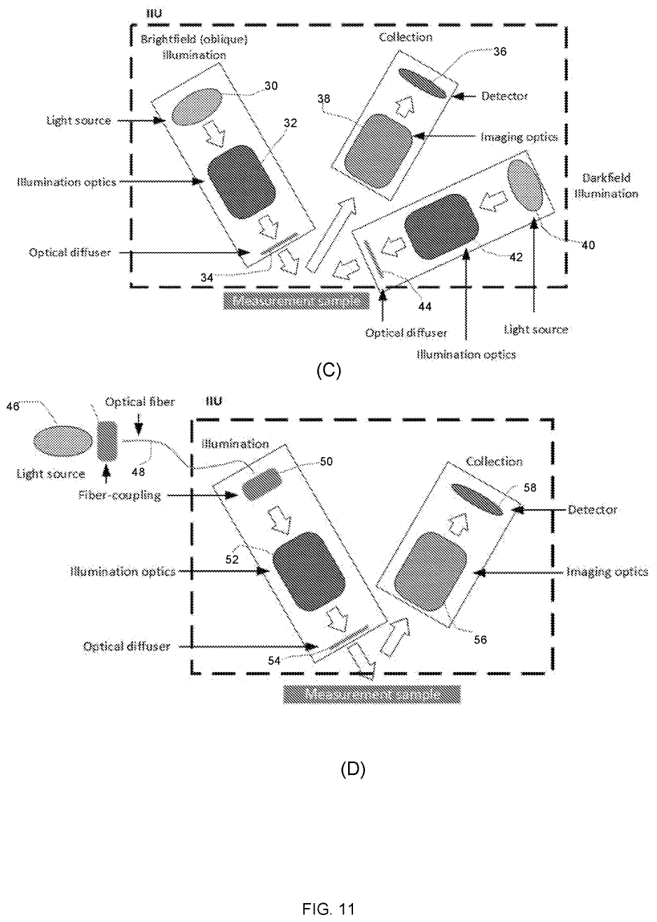

FIG. 11 (part (C)) illustrates a collection unit (including imaging optics 38 and detector 36) having an oblique optical axis, a brightfield illumination unit (including light source 30 and illumination optics 32 as well as optical diffuser 34) having an oblique optical axis, and a dark field illumination unit (including light source, illumination optics 42 and optical diffuser 44) having an oblique optical axis.

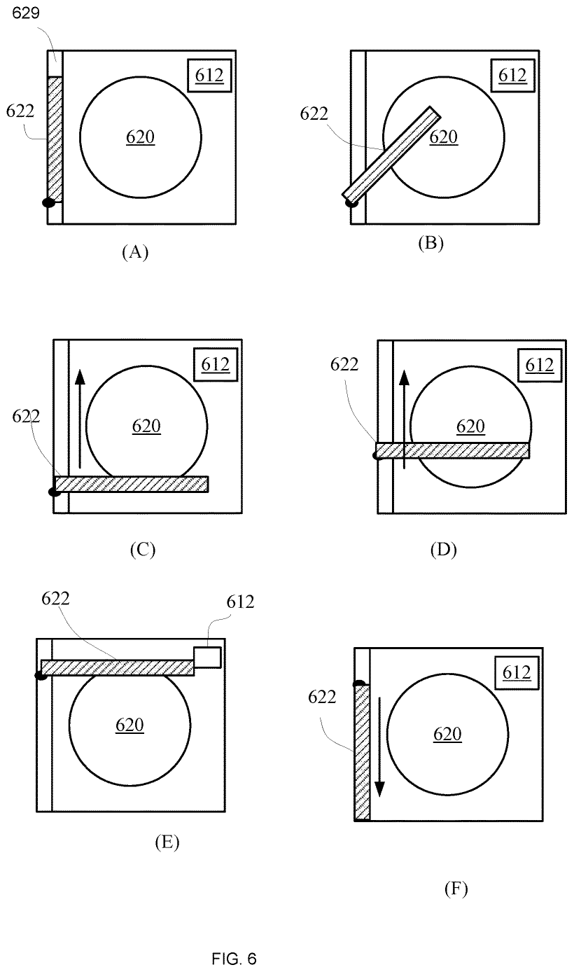

Another possible benefit requires a modification of the integration layout, by which the IIU module can be folded on both ends of the sweep sequence (see FIG. 6). Under such conditions, the throughput benefit can be significant as the number of required IIU movements above the sample is reduced FIG. 6 illustrates a long-IU folding-module integration. FIG. 6 part (A) illustrates a long IIU module that is stored at the enclosure edge. FIG. 6 part (B) and part (C) illustrate deployment by rotation. FIG. 6 part (C), (D) and (E) illustrate a scan of the sample. To save time, the IIU is stored again by folding it the enclosure edge—see FIG. 6 part (F).

According to an embodiment, the integrated system includes motorization required for deployment and motion of the IIU. The required motors impose both additional cost and volume requirements from the overall solution, which are both significantly limited.

One possible mitigation is based on using the OH, with its existing motorization, for either the deployment and\or translation of the IIU head.

Deployment may involve having the OH travel to the IIU edge, connects to it (mechanically, electrostatically, magnetically or by any other means) and rotates it to its deployed position.

Motion—similar to deployment and after creating a mechanical link between the OH and the IIU, the OH motors are used to carry the IIU during scan.

There may be provided rails and rails interfaces (for example x-axis rails denote 525 in FIG. 6 and y-axis rails denoted 626 in FIG. 6. According to an embodiment, the x-axis rails may be spaced by a distance that exceeds the width of the sample and the y-axis rails may be movable outside the path of the sample). According to an embodiment the sample is not moved through a plane that includes the rails—and thus the rails may be closer to each other and/or not need to move away from the path of the sample.

One concern in this integration scheme relates to the mechanical stability of the IIU module. As it is held exclusively by an axis placed on its edge, a significant mechanical torque is created on the hinges. Such situation can lead to a tilting of the IIU, potentially further degrading with time. As the IIU imaging performance depend on its distance to the sample (as dictated by the optical system depth of focus), these imperfections could have adverse impact on the image quality and overall module performance.

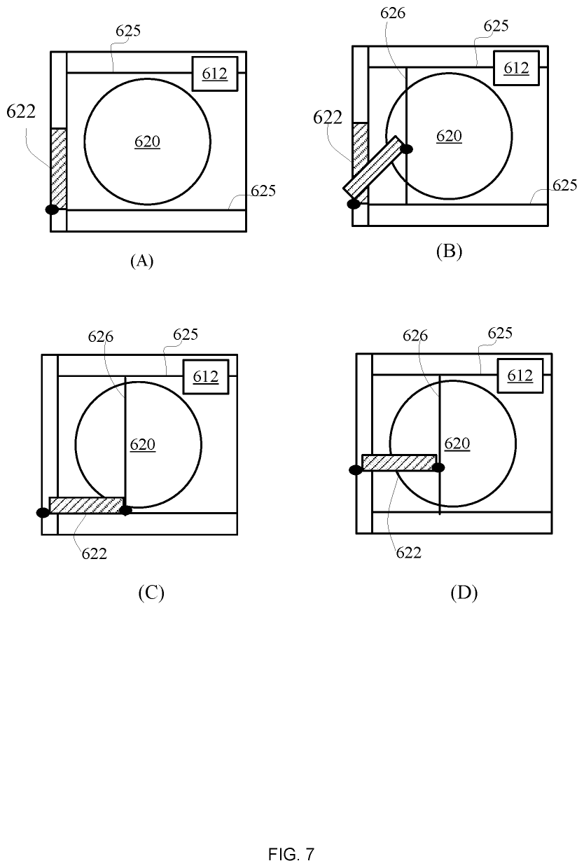

One mitigation to this challenge involves the addition of a second weight-carrying axis on which the IIU is carried (see the x-axis rails and the y-axis rails of FIG. 7). Such implementations guarantee the IIU remains rigid and at fixed distance to the measured sample. FIG. 7 also illustrated OH 612.

FIG. 7 illustrates additional weight-carrying axes (denoted 626) offering improved mechanical stability and rigidness. FIG. 7 part (A) illustrates the IIU module 629 being connected on both ends to lateral (‘y’) axes, through rotation-free bearings (marked by dark squares). FIG. 7 parts (B), (C) and (D) illustrate deployment and scanning the sample while both ends of the IIU remain connected to rails, maintaining its alignment.

Parallel IIU and IM measurements may be executed more quickly when parallelism is applied.

According to an embodiment, the IIU module can cover half the sample area at a time. During its scan, the second sample half can be measured with the IM OH. After the sample is rotated—allowing the IIU to scan the second sample half, the IM OH can correspondingly complete its sample coverage.

In such an approach, throughput hit imposed by serially executed IIU measurements and IM is reduced.

Static IIU through rotating-polarization \non-polarized imaging.

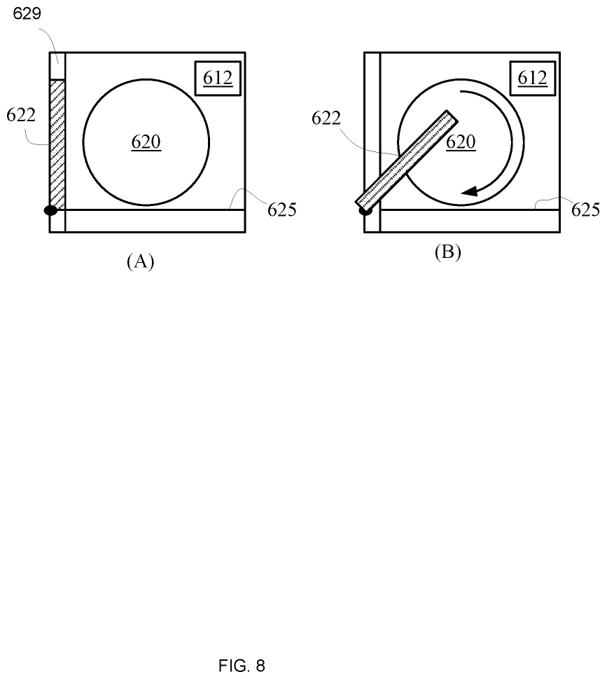

Arguably, the simplest implementation of full-sample imaging involves a static IIU placed above the sample, with sample rotation used to obtain full coverage. One possibility for such implementation is presented in FIG. 8, and involves a similar deployment of an IIU by rotation from its storage at the enclosure edge as discussed above. However, in this implementation, the IIU is rotated until it spans a radial range across the sample, from the sample edge to its center location. Next. the sample is rotated and IIU image acquisitions take place providing full sample coverage with no further motion of the IIU.

FIG. 8 part (A) illustrates a small-footprint IIU module is folded to the side of the MU. FIG. 8 part (B) illustrates a deployment of the IIU by rotation until the IIU is placed above the sample, reaching the sample.

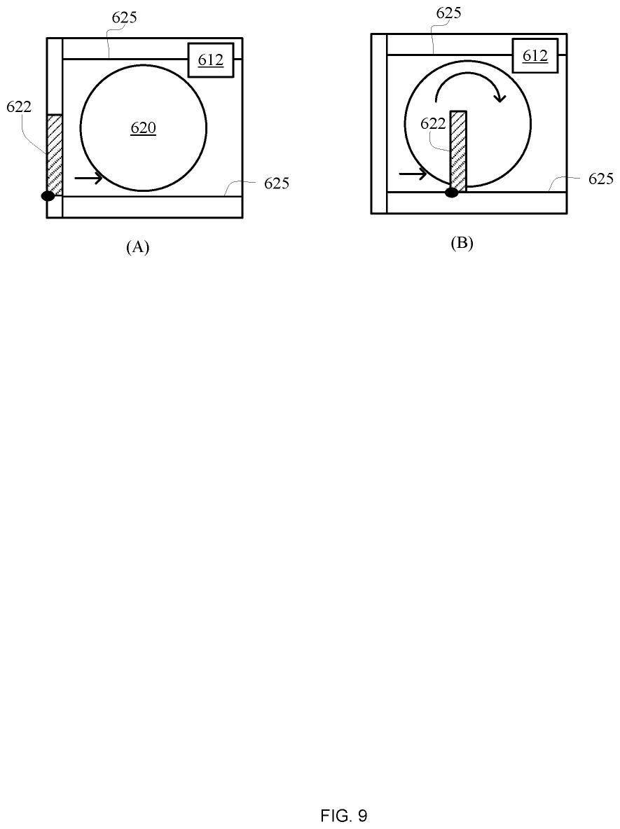

Alternatively, the IIU can be moved laterally and placed such that it covers a radial span across the sample-as shown in FIG. 9 parts (A) and (B).

Since typically the IM stage already allows accurate, well-controlled rotation of the sample, such implementation is mechanically simple. However, several unique challenges raised by this approach require high-end solutions:

### Polarization Control

One of the most challenging aspect involved in this implementation relates to polarization. When illumination and or collection paths are polarized or even partially polarized, the acquired images could significantly change when measured at different orientations. As this implementation is inherently based on measuring each region of the sample at a different azimuth, any polarization in the imaging apparatus would lead to significant across-sample variations in the IIU image, regardless of the actual sample characteristics. Under such conditions, interpretation of the measured image, correlating it to external references and across-sample comparative statistics is almost impossible.

One possible mitigation to the polarization challenge involves using non-polarized illumination and collection. Achieving completely non-polarized optical path is highly nontrivial, but could be obtained through a high-end dedicated optical design.

Another possibility involves introducing intentional polarization to the illumination and collection paths. Specifically, by imposing circular polarization, the dependence on sample orientation can be removed.

Alternatively, circular polarization can be used for illumination only. At collection, a polarization-resolved imaging camera can be used. Such cameras provide full polarization information on the reflected light, including reflected intensity at each polarization and the ellipsometric phase. While in such configuration measurements would still depend on the sample orientation, it is straightforward to use the measured polarization information in order to remove this dependence. Another side-benefit of such an approach involves the acquisition of polarized imaging information, offering additional sensitivity to sample characteristics.

In another possible implementation, a rotating polarization control is added to the optical path. Such an element rotates the polarization (at illumination and collection) in correspondence with the sample orientation, so that measurements at any sample azimuth are equivalent. While various solutions exist to control polarization, for this specific implementation a liquid-crystal polarization control is uniquely suitable, allowing easy, cheap and lightweight integration.

### Image Processing for Radial Acquisition

In addition to the challenge posed by polarization, this scheme suffers from a related image-processing challenge. As the IIU module covers a radial span across the sample, during each acquisition pixels close to the sample center travel a small distance whereas pixels near the sample rim travel a large distance. Compiling the set of images into a single calibrated image with no irregularities and distortions represents a significant algorithmic challenge.

In addition to these integration approaches, several important implementation details could offer significant advantages.

### Separated, External Illumination

As explained, the IIU is required to be lightweight, small and create minimal heating of its environment. However, this module requires an illumination apparatus, imaging optical setup and detection—all integrated into the same volume.

An elegant mitigation involves separating the illumination apparatus from the IIU. This can involve moving the electronics, control and even light-creation device itself to a separated location in the IM tool (e.g. below or above the measurement unit). The electronic signal, light or both are then carried to the IIU using cables\optical fibers.

Another possibility offering similar benefits involves generating the illumination outside the MU enclosure and guiding the generated light into the MU using free-space optics. While such an approach is significantly more complicated to implement than using fiber optics, it solves the need to deal with moving optical fibers (which is a known source for light homogeneity instabilities) and could offer more flexible shaping of the light beam as required for illuminating the wide area required. Specifically, some implementations using free-space optics could solve the problem of spreading the illuminated light across the imaged region.

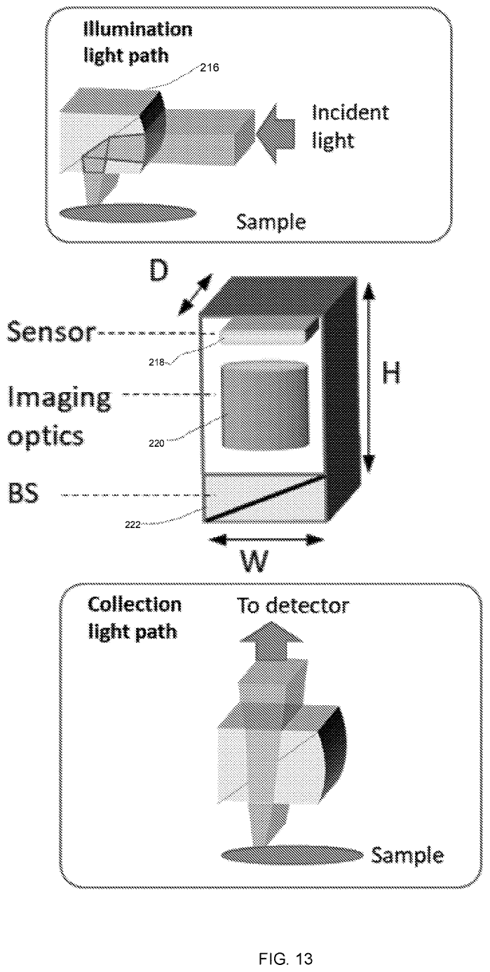

FIGS. 10-12 illustrates six examples (denoted example (A)-example (F) of IIUs. FIG. 13 illustrates optical components of the integrated circuit.

FIG. 10 (part (A)) illustrates sample 620, and IIU that includes a collection unit (including imaging optics 18 and detector 16) having an oblique optical axis, and an illumination unit (including light source 10, illumination optics 12 and optical diffuser 14) having an oblique optical axis configured to receive reflected radiation from the sample.

FIG. 10 (part (B)) illustrates sample 620, and an IIU that includes beam splitter 24, a collection unit (including imaging optics 28 and detector 26) having a normal optical axis, and an illumination unit (including light source 20 and illumination optics 22) having a horizontal optical axis that is converted, by the beam splitter to a normal optical axis.

FIG. 11 (part (D)) illustrates an external light source 46 optically coupled by fiber 48 to an illumination unit (including fiber coupler 58, illumination optics 52 and optical diffuser 54) that has an oblique optical axis and belongs to an IIU that also includes a collection unit (including imaging optics 58 and detector 56) having an oblique optical axis.

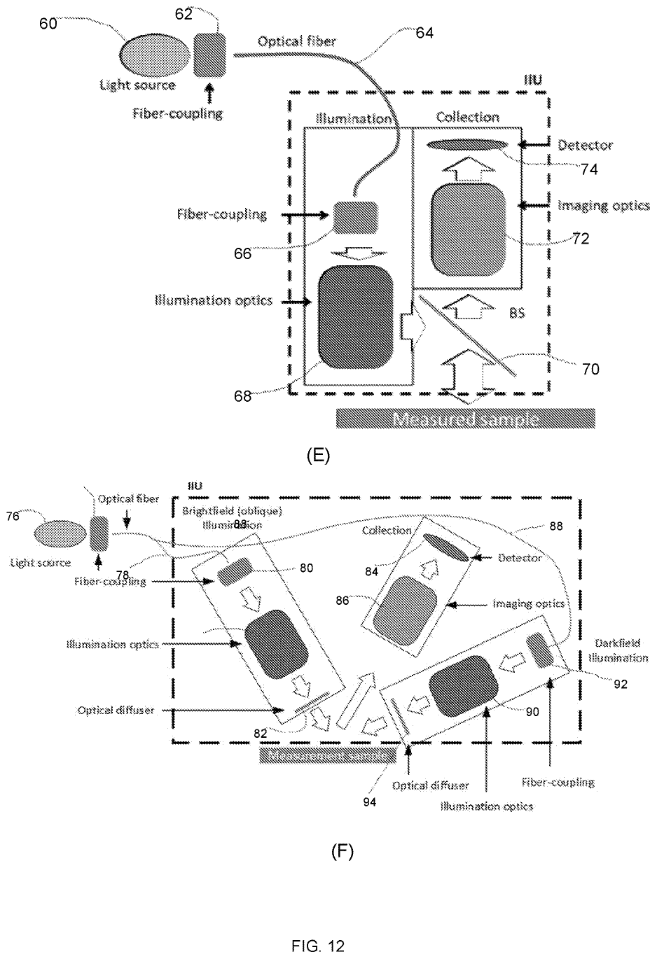

FIG. 12 (part E) illustrates an external light source 60 optically coupled (using fiber coupling 62) by fiber 64 to an illumination unit (including fiber coupling 66 and illumination optics 68) of an IIU and having an horizontal optical axis that is converted, by the beam splitter to a normal optical axis. The IIU also includes beam splitter 70 and collection unit (including imaging optics 72 and detector 74) having a normal optical axis.

FIG. 12 (part (F)) illustrates sample 620 and an IIU that includes a collection unit (including imaging optics 86 and detector 84) having an oblique optical axis, a brightfield illumination unit (including fiber coupling 78, illumination optics 32 and optical diffuser 82) having an oblique optical axis, and a dark field illumination unit (including fiber coupling 92, illumination optics 42 and optical diffuser 44) having an oblique optical axis. The fiber couplings (78 and 92) are optically coupled (via fibers 78 and 88) to an external light source 76.

There are provided several possible integration schemes, offering both the potential of ultra-small and lightweight IIU module along with highly stable illumination path. There schemes may involves free-space illumination. For concreteness, one implementation of the proposed approach is depicted in FIG. 3. In this case, the measurement unit is placed on a motion apparatus (FIG. 3 part (A)) which scans the measurement unit across the sample, providing full-sample imaging (FIG. 3 part (B)).

These schemes include disjointed illumination and measurement unit and illumination optics directing the illuminated light in a predominantly parallel plane to the measured sample (see FIG. 3). The horizontal beam is referred to as ‘illumination sheet’. FIG. 3 illustrates IIU as including measurement unit (200, 208) including sensor and beam splitter) motion apparatus (201, 211) located below sample but having interfaces (202, 204, 210, 212) that move the measurement unit located above sample towards the illumination sheet generated by illumination unit (206, 214).

A measurement unit including a beam-splitter (BS), providing two separate functions (FIG. 13 part (A)): (i) Optics redirecting light coming from the illumination unit towards the sample and (as needed) focusing the beam, and (ii) an optical collection path, receiving light reflected from the measured sample and imaging it onto a sensor.

The measurement unit is required to be of very limited dimensions due to the associated integration considerations. Specifically, its width and height (see ‘W’ and ‘H’ at the bottom of FIG. 13) are limited to several cm or very few tens of cm at most. Conversely, the lateral dimension (‘D’ in FIG. 13) can have a larger length, up to fully covering the entire sample extent.

The scheme of FIGS. 3 and 13 offers the combined advantages of allowing the (moving) measurement unit to have very small volume, light weight and with negligible heat generation. In parallel, as no moving optical fibers are involved, this solution does not suffer from any related fluctuations and instabilities.

According to an embodiment, the illumination path: responsible for creating a homogeneous, well-defined illumination sheet and coaxial illumination.

Imaging collection path: imaging optics used to generate an image of the measured sample on a sensor.

The goal of the illumination unit is to generate the sheet of light directed towards the measurement unit in such a way so as to allow its focusing on the measured sample.

There is provided proposed a design that inherently separates the measurement unit from the heat generated by the light source. However, if significant heat is created in the illumination unit, it may affect the volume at which measurements are taken adversely causing degradation in the metrology quality.

It is therefore preferable to have the light source further separated from the illumination unit, and light guided to the illumination unit using free-space optic or optical fibers.

Illumination homogenization. At the illumination unit, the incident light will be homogenized (using such optical elements as diffusers). Such homogenization can also be implemented (in addition or instead) at the measurement unit.

Light sheet generation. Forming the illumination beam into a horizontal sheet-like shape can be implemented in several ways, most readily using a cylindrical lens.

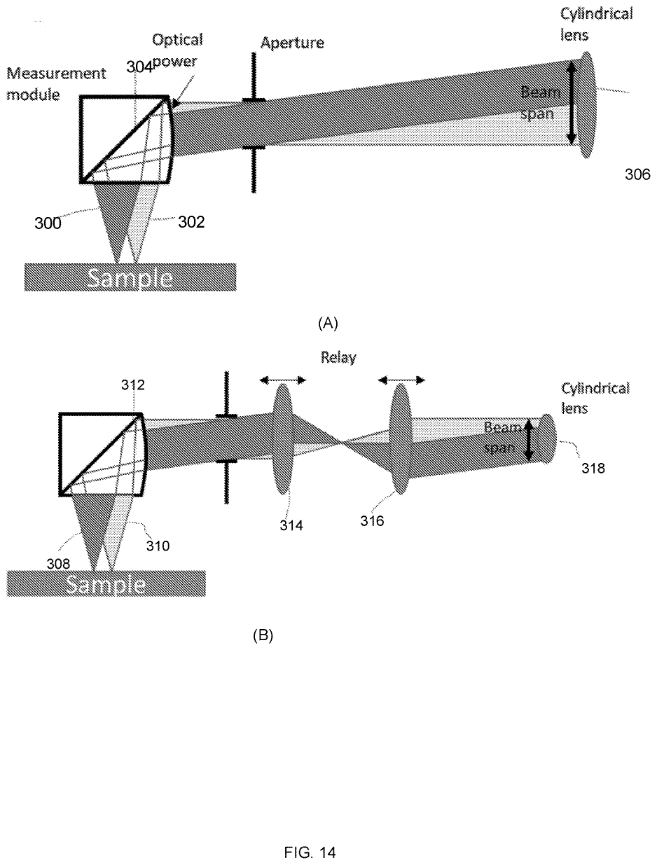

FIG. 14 part (A) presents one possible implementation for the optical path. The optical path includes cylindrical lens 306, aperture, and beam splitter including tilted facet 304 that faces an illumination source (downstream to the cylindrical lens) and has optical power, and focuses the incident beam on the sample. Alternatively, this optical power can be situated at the beam splitter facet facing the sample. In such a case, the imaging optics at the detection path has to take this power into consideration. FIG. 14 part (A) illustrates two illumination beams 300 and 302.

An aperture is placed in such a location so as to guarantee telecentric (or approximately telecentric) illumination. This is of high importance in order to assure measurements are not position-dependent.

One challenge raised by such an implementation relates to the beam span at the illumination module position, when the measurement unit is far from its position. Under such conditions, beam divergence (arising from the finite extent of the illumination spot on the sample) can become significant, requiring large, complicated optics.

One mitigation to this challenge is reducing the span of the illuminated area, and acquiring images at high frequency during the measurement module motion. The narrow-sized images are then stitched algorithmically into a large-field image.

Another possibility includes the addition of an optical relay (formed of lenses 316 and 314 that are located between cylindrical lens 318 and the aperture), which would significantly reduce the beam extent (FIG. 14 part (B)). In such implementation, the relay lenses have to be moved in accordance with the measurement module. The tilted facet of the beam splitter is denoted 312 and has optical power. FIG. 14 part (B) also illustrates two beams 308 and 310.

In FIG. 14 part (A) a cylindrical lens is used to direct light from the light source (to its right, not shown in the sketch) and create the light sheet. An aperture is used to create telecentric illumination, and focusing power is implemented on one facet of the BS. FIG. 14 part (B) illustrates a possible mitigation to the challenge of large beam extent is based on adding a pair of lenses creating an optical relay. As the measurement module is scanned across the sample, these lenses have to be correspondingly moved.

### Imaging Collection Path

At the collection path, light reflected from the sample needs to be imaged onto the sensor. Various imaging optics layouts can be used for this end. However, of specific importance for the current invention is the use of Graded Index (GRIN) Lenses. These lenses offer extremely small integration volumes, and were especially developed for such small-footprint solutions. A pair of oppositely-jointed GRIN lenses create a highly compact imaging solution.

Detailed description of GRIN lens technology is well known and will not be further elaborated here.

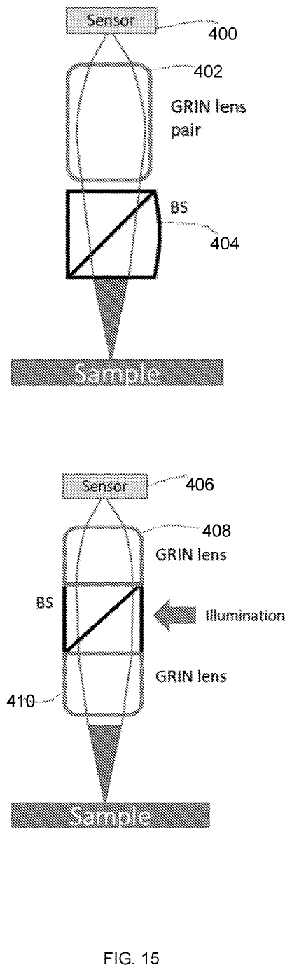

Two examples for how GRIN lenses can be used in the current module are presented in FIG. 15.

FIG. 15 part (A)—an implementation using a GRIN lens pair 402 between sensor 400 and beam splitter 404 that is downstream to sample 620. FIG. 15 part (B) illustrates an illumination that is coaxially combined into the optical path (using beam splitter) between the two GRIN lenses 410 and 408, using the second GRIN lens for focusing. The two GRIN lenses are located between sensor 406 and the sample.

The suggested examples of integrated systems benefit from having a compact volume, low weight, low heat generation at the metrology region and measurement stability.

The suggested examples of integrated systems benefit from their low cost-as they use simple and cheap optical elements, as well as convenient cost optimization of the separate modules (illumination, measurement).

The suggested examples of integrated systems benefit from simple integration. Especially—the separation of the illumination unit resolves several significant integration challenges, such as mechanical stability, motion control, weight balancing etc.

According to an embodiment there are provided methods for evaluating sample using any of the mentioned above integrated systems.

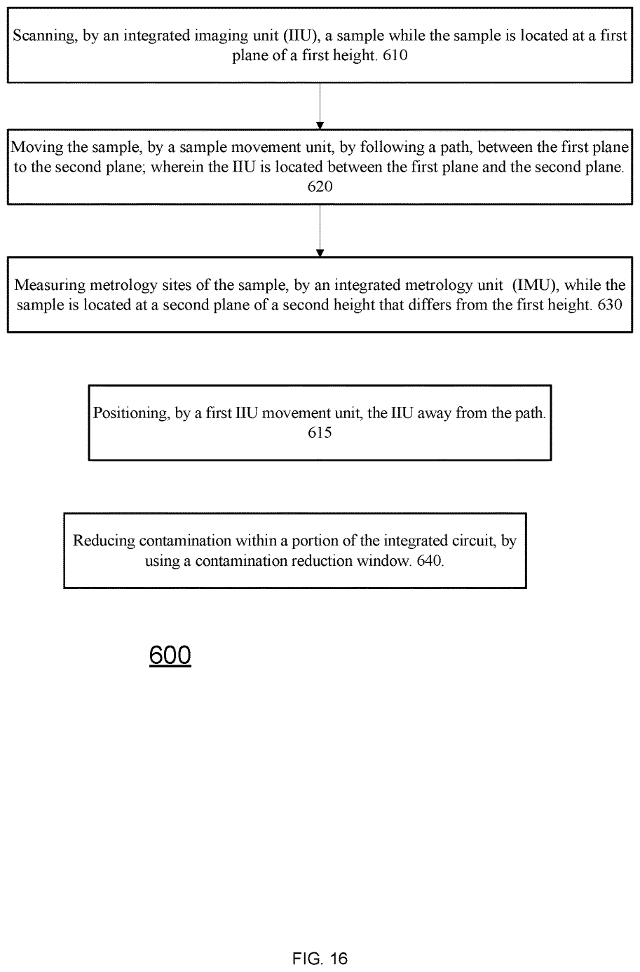

FIG. 16 illustrates an example of method 900 for operating an integrated system.

According to an embodiment, method 600 includes steps 610, 620 and 630.

According to an embodiment, step 610 includes scanning, by an integrated imaging unit (IIU), a sample while the sample is located at a first plane of a first height.

According to an embodiment, step 630 includes measuring metrology sites of the sample, by an integrated metrology unit (IMU), while the sample is located at a second plane of a second height that differs from the first height. In various figures the first plane is located below the second plane but the first plane may be located above the second plane.

According to an embodiment step 620 includes moving the sample, by a sample movement unit, by following a path, between the first plane to the second plane; wherein the IIU is located between the first plane and the second plane.

According to an embodiment, step 610 is followed by step 620 that is followed by step 630.

Following the completion of step 630 the method may include reversing step 620—and positioning the sample at the first plane.

According to an embodiment, the method includes mechanically coupling, by an interface, the integrated system to sample related system.

According to an embodiment, the method includes step 615 of positioning, by a first IIU movement unit, the IIU away from the path, during the moving of the sample along the path.

According to an embodiment, step 620 includes moving, by a second IIU movement unit, the IIU during the scan of the sample.

According to an embodiment, the second IIU movement unit includes one or more rails and one or bearings for interfacing with the one or more rails during the movement of the IIU during the scan of the sample.

According to an embodiment, the one or more rails are located outside the path.

According to an embodiment, the IIU includes a beam splitter that is shared between an illumination sub-unit of the IIU and a collection sub-unit of the IIU.

According to an embodiment, step 620 includes illuminating the sample, by the IIU, during the scan of the sample, by oblique illumination.

According to an embodiment, step 620 includes illuminating the sample, by the IIU, during the scan of the sample, by normal illumination.

According to an embodiment, a dimension of the integrated system ranges between one to one and a half times a corresponding dimension of the sample.

According to an embodiment, method 600 includes step 640 of reducing contamination within a portion of the integrated circuit, by using a contamination reduction window. Step 640 is optional.

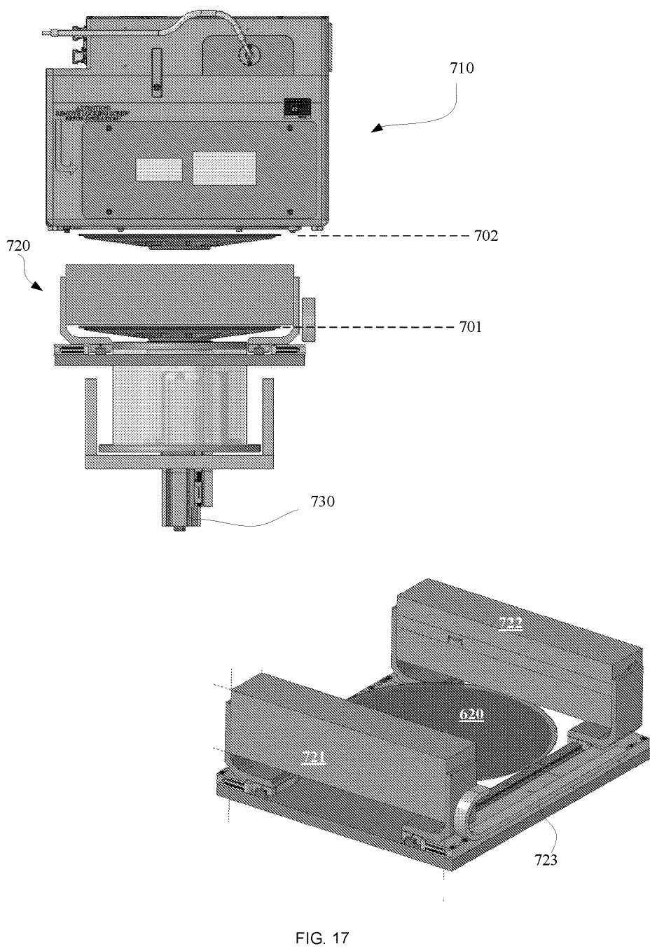

FIGS. 17-19 illustrates an example of an integrated system that includes IIU 720 configured to scan a sample 620 while the sample is located at a first plane 701 of a first height and an IMU 710 configured to measure metrology sites of the sample while the sample is located at a second plane 702 of a second height that differs from the first height; and (iii) a sample movement unit such as stage 730 configured to move a sample, by following a path, between the first plane to the second plane. The IIU is located between the first plane and the second plane.

FIG. 17 also illustrates the IIU 720 as including illumination head 722, collection head 721 (also referred to as measurement unit) that moves towards the illumination unit by second IMU movement unit 723 that includes rails, sliders and a motor.

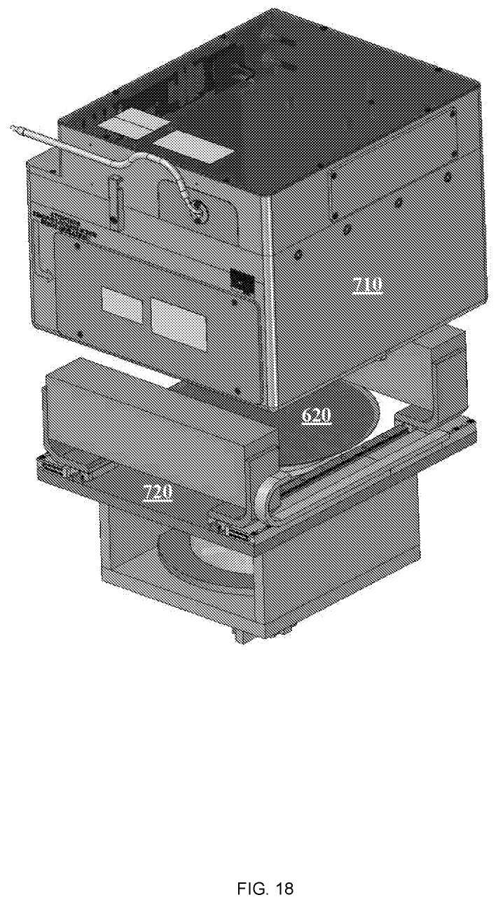

FIG. 18 illustrates the IIU 720, the sample 620 (positioned at a first plane) and the IMU 710.

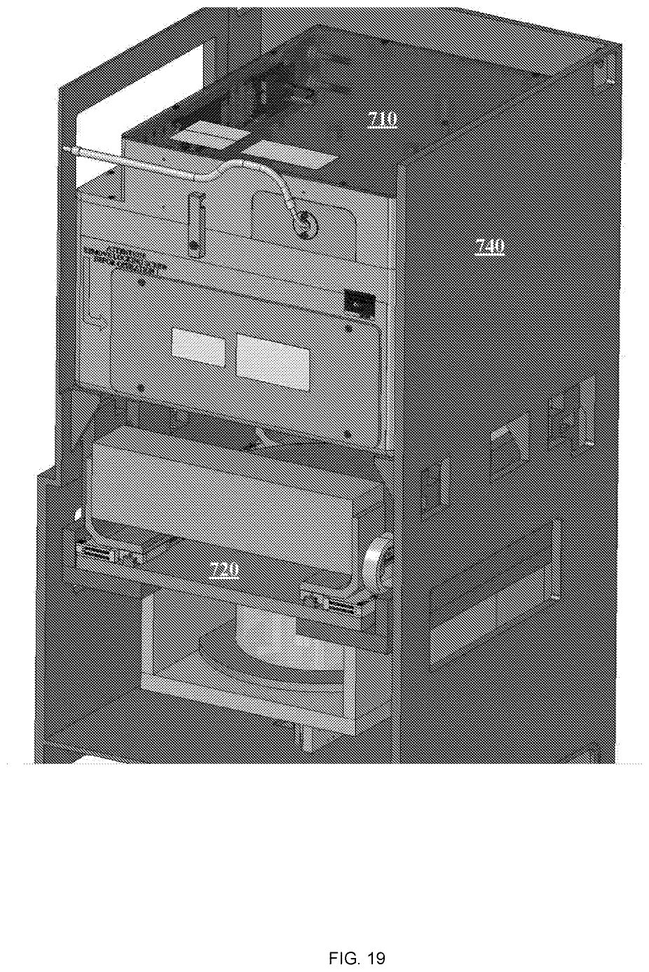

FIG. 19 illustrates the IIU 720, the sample 620 (positioned at a first plane) the IMU 710, and an internal enclosure 730 that surrounds the IIU 720, the IMU 710.

The integrated system has inputs for exchanging the sample between the integrated system and the sample related system, and for exchanging the sample with another unit or robot, and the like. The integrated system also includes a man machine interface (for example a keyboard and a screen).

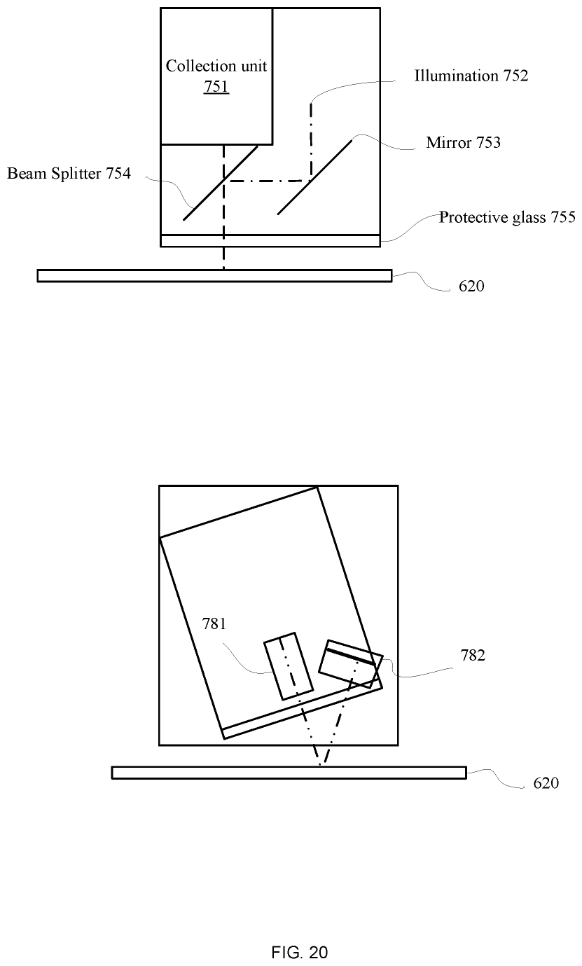

FIG. 20 is an example of the IIU in a normal illumination configuration (FIG. 20 part (A)) and in an oblique illumination configuration (FIG. 20 part (B)).

The normal illumination configuration includes collection unit 751, beam splitter 754, mirror 753 and an optional protective glass 755. Illumination radiation 752 illuminates the mirror 753 to be reflected towards the beam splitter and to reflected towards the sample 620.

The oblique illumination configuration includes illumination unit 781 and collection unit 782 (including detector)—both having oblique angle optical axis.

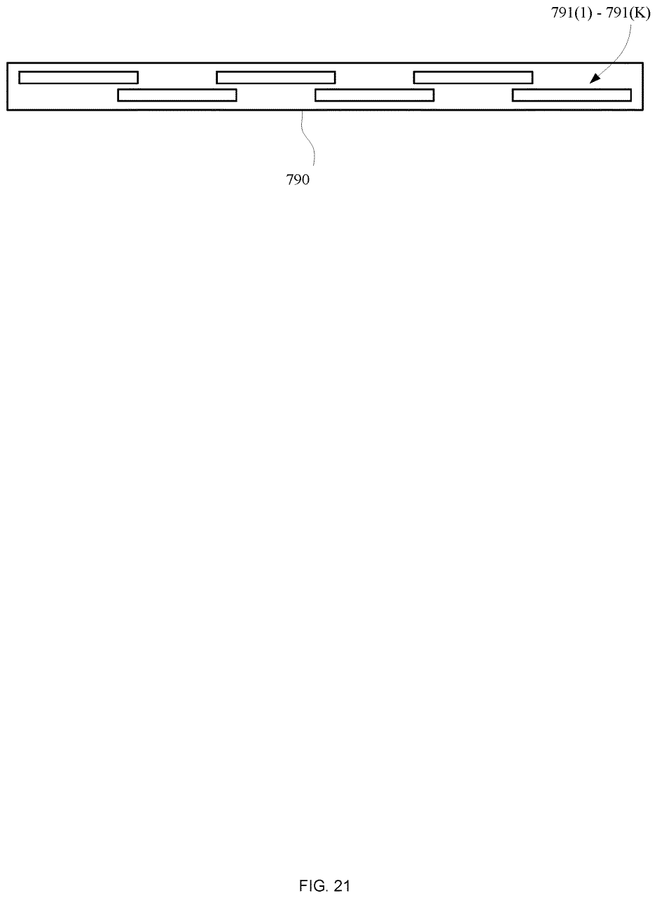

FIG. 21 illustrates a sensor 720 that is made of sensing elements 791(1)-791(K) arranges in two linear arrays that are proximate to each other—for example the angular deviation between light reaching the two linear arrays is in a magnitude of 0.05-0.15 milliradians. K may range between two and twenty—or more. In FIG. 21 the linear arrays are parallel to each other and parallel to a longitudinal axis of the sensor. There is an overlap, along the longitudinal axis, between adjacent sensing elements of different linear arrays.

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that can be executed by the system and should be applied mutatis mutandis to a non-transitory computer readable medium that stores instructions that once executed by a computer result in the execution of the method.

The mentioned above text may refer to a sample. A sample—especially a semiconductor sample—is merely an example of a sample.

The mentioned above text may refer to a light emitting diode (LED). This is merely an example of an illumination source.

The mentioned above text refers to a wavelength. Any reference to a wavelength should be applied mutatis mutandis to a range of wavelengths. Additionally or alternatively—any reference to a wavelength may be applied mutatis mutandis to any other property of the illumination and/or collection—such as, polarization, angular content of illumination or/and collection beams, and the like.

Any reference to the term “comprising” or “having” should be interpreted also as referring to “consisting” of “essentially consisting of”. For example—a method that comprises certain steps can include additional steps, can be limited to the certain steps or may include additional steps that do not materially affect the basic and novel characteristics of the method—respectively.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim

1. An integrated system, comprising:
an integrated imaging unit (IU) configured to scan a sample while the sample is located at a first plane of a first height;
an integrated metrology unit (IMU) configured to measure metrology sites of the sample while the sample is located at a second plane of a second height that differs from the first height; and
a sample movement unit configured to move a sample, by following a path, between the first plane to the second plane; wherein the IIU is located between the first plane and the second plane.

2. The integrated system according to claim 1, comprising an interface for mechanically coupling the integrated system to sample related system.

3. The integrated system according to claim 1, comprising a first IIU movement unit that is configured to position the integrated imaging unit away from the path, during a movement of the sample along the path.

4. The integrated system according to claim 1, comprising a second IIU movement unit that is configured to move the IIU during the scan of the sample.

5. The integrated system according to claim 2, wherein the second IIU movement unit comprising one or more rails and one or bearings for interfacing with the one or more rails during the movement of the IIU during the scan of the sample.

6. The integrated system according to claim 5, wherein the one or more rails are located outside the path.

7. The integrated system according to claim 1, wherein the IIU comprises a beam splitter that is shared between an illumination sub-unit of the IIU and a collection sub-unit of the IIU.

8. The integrated system according to claim 1, wherein the integrated imaging unit is configured to illuminate the sample, during the scan of the sample, by oblique illumination.

9. The integrated system according to claim 1, wherein a dimension of the integrated system ranged between one to one and a half times a corresponding dimension of the sample.

10. The integrated system according to claim 1, further comprising a contamination reduction window configured to reduce contamination within a portion of the integrated system.

11. A method for operating an integrated system, the method comprising:
scanning, by an integrated imaging unit (IU), a sample while the sample is located at a first plane of a first height;
measuring metrology sites of the sample, by an integrated metrology unit (IMU), while the sample is located at a second plane of a second height that differs from the first height; and
moving the sample, by a sample movement unit, by following a path, between the first plane to the second plane; wherein the IIU is located between the first plane and the second plane.

12. The method according to claim 11, comprising mechanically coupling, by an interface, the integrated system to sample related system.

13. The method according to claim 11, comprising positioning, by a first IIU movement unit, the IIU away from the path, during the moving of the sample along the path.

14. The method according to claim 11, comprising moving, by a second IIU movement unit, the IIU during the scan of the sample.

15. The method according to claim 12, wherein the second IIU movement unit comprising one or more rails and one or bearings for interfacing with the one or more rails during the movement of the IIU during the scan of the sample.

16. The method according to claim 15, wherein the one or more rails are located outside the path.

17. The method according to claim 11, wherein the IIU comprises a beam splitter that is shared between an illumination sub-unit of the IIU and a collection sub-unit of the IIU.

18. The method according to claim 11, comprising illuminating the sample, by the IIU, during the scan of the sample, by oblique illumination.

19. The method according to claim 11, wherein a dimension of the integrated system ranged between one to one and a half times a corresponding dimension of the sample.

20. The method according to claim 11, comprising reducing contamination within a portion of the integrated circuit, by using a contamination reduction window.
